(19) United States
(12) Patent Application Publication
(10) Pub. No.: US 2026/0282956 A1
(43) Pub. Date: Sep. 17, 2026

(54) CHIP PACKAGE WITH SILICON BRIDGE

(71) Applicant: Advanced Micro Devices, Inc., Santa Clara, CA (US)

(72) Inventors: Deepak Vasant KULKARNI, Austin, TX (US); Alan D. SMITH, Austin, TX (US); Raja SWAMINATHAN, Austin, TX (US); Manish DUBEY, Lakeway, TX (US); Kaushik MYSORE, Austin, TX (US)

(21) Appl. No.: 19/668,690

(22) Filed: May 5, 2026

Related U.S. Application Data
(63) Continuation-in-part of application No. 18/615,918, filed on Mar. 25, 2024.
(60) Provisional application No. 63/596,709, filed on Nov. 7, 2023.

(51) Int. Cl. H10W 70/60; H10B 80/00; H10W 20/20; H10W 44/00; H10W 72/00

(52) U.S. Cl. CPC H10W 70/618; H10B 80/00; H10W 20/211; H10W 44/601; H10W 72/823

(57) ABSTRACT

Disclosed herein are chip packages and electronic devices that utilized a silicon bridge having a memory controller to interface between a logic device having at least one compute die and one or more memory stacks within a singular chip package. In one example, a chip package is provided that a substrate, a plurality of silicon bridges, a redistribution layer, a logic device, and a memory stack. The plurality of silicon bridges are disposed in a common layer and electrically and mechanically coupled to the substrate. At least a first silicon bridge of the plurality of silicon bridges includes a plurality of decoupling capacitors. The redistribution layer is disposed on the plurality of silicon bridges. The logic device is disposed over the redistribution layer and includes one or more compute dies. The memory stack is disposed over the redistribution layer adjacent the logic device.

### CROSS REFERENCE TO RELATED APPLICATION

This application is a continuation in part of U.S. Patent Application Serial No. 18/615,918 filed Mar. 25, 2025, and also claims priority to the U.S. Provisional Patent Application Serial No. 63/596,709 filed Nov. 7, 2023, both of which are incorporated herein by reference in their entirety.

### TECHNICAL FIELD

Embodiments of the present invention generally relate to chip packages having memory stacks, and in particular, chip packages and electronic devices that utilize a silicon bridge having one or more IP blocks, such as a memory controller, to interface between one or more compute die stacks and one or more memory stacks within a singular chip package.

### BACKGROUND

Electronic devices, such as tablets, computers, copiers, digital cameras, smart phones, control systems, automated teller machines, data centers, artificial intelligence system, and machine learning systems among others, often employ electronic and/or photonics components which leverage chip packages for increased functionality and higher component density. Conventional chip packaging schemes often utilize a package substrate, often in conjunction with a through-silicon-via (TSV) interposer substrate and/or other such as FanOut and/or passive silicon bridges and/or substrate with glass and/or Si and/or organic core, to enable a plurality of integrated circuit (IC) dies to be mounted to a single package substrate. The IC dies are mounted to a top surface of the package substrate while a bottom surface of the package substrate is mounted to a printed circuit board (PCB).

In many applications, memory dies are integrated into the chip package to reduce the distance between the memory dies and compute dies of the chip package. The shortened distance reduces power consumption and increases device performance. One type of chip package having both a stack of memory dies and at least one connected compute die is known as a high bandwidth memory (HBM). The HBM stack conventionally includes an I/O buffer die upon which the memory dies are stacked. The I/O buffer die also includes the memory controller. However, in most conventional chip packages having a HBM die stack generally have compute dies that have complex route between each compute die and the I/O buffer and memory dies of a particular HBM die stack, often requiring routing through the package substrate. The complex routing creates scheduling complexity that slows device performance. Additionally, the complex routing often requires a larger, more expensive interposer and package substrate to accommodate the increased number of routing traces without generating excessive unwanted noise. The larger interposers and package substrates increase the manufacturing complexity and cost, and contribute to slower performance, which are all undesirable.

Therefore, a need exists for improved chip packages that efficiently interface one or more compute die stacks and one or more memory stacks within a singular chip package.

### SUMMARY

Disclosed herein are chip packages and electronic devices that utilize a silicon bridge having active and/or passive circuitry, to interface between a logic device having at least one compute die and one or more memory stacks within a singular chip package.

In one example, a chip package is provided that includes a substrate, a plurality of silicon bridges, a redistribution layer, a logic device, and a memory stack. The plurality of silicon bridges are disposed in a common layer and electrically and mechanically coupled to the substrate. At least a first silicon bridge of the plurality of silicon bridges includes a plurality of decoupling capacitors. The redistribution layer is disposed on the plurality of silicon bridges. The logic device is disposed over the redistribution layer and includes one or more compute dies. The memory stack is disposed over the redistribution layer adjacent the logic device.

In some examples, the plurality of decoupling capacitors of the first silicon bridge are deep trench capacitors. The plurality of decoupling capacitors of the first silicon bridge may be metal insulator metal (MIM) capacitors and/or metal-oxide-semiconductor (MOS) capacitors.

In some examples, the first silicon bridge comprises through silicon vias.

In some examples, the plurality of silicon bridges further comprises a second silicon bridge containing one or more active devices.

In another example, a chip package is provided that includes a substrate, a memory stack, a layer of mold compound, a redistribution layer, a logic device, and a plurality of silicon bridges. The redistribution layer is disposed on the layer of mold compound. The logic device is disposed over the redistribution layer and includes one or more compute dies. The memory stack is disposed over the redistribution layer adjacent the logic device. The plurality of silicon bridges are disposed in the layer of mold compound. At least a first silicon bridge of the plurality of silicon bridges includes a plurality of decoupling capacitors coupled with the logic device.

In another example, a chip package is provided that includes a substrate, a layer of mold compound, and a redistribution layer disposed on the layer of mold compound. A logic device is disposed over the redistribution layer and includes one or more compute dies, and a memory stack is disposed over the redistribution layer adjacent to the logic device. The chip package further includes a plurality of silicon bridges disposed in the layer of mold compound, where at least a first silicon bridge includes a plurality of deep trench capacitors coupled with the logic device and further includes through silicon vias. Additionally, a conductive post extends through the mold compound.

In other examples, a chip package is provided that includes a substrate, a logic device, a memory stack, and a silicon bridge. The logic device is disposed over the substrate. The logic device includes one or more compute dies. The memory stack is disposed over the substrate to adjacent the logic device.

In another example, a chip package is provided that includes a substrate, a logic device, a memory stack, a silicon bridge, and a redistribution layer. The logic device is disposed over the substrate. The logic device includes one or more compute dies. The memory stack is disposed over the substrate adjacent the logic device. The silicon bridge has a physical interface layer and memory controller circuitry. The physical interface layer is disposed below the logic device. The memory controller circuitry includes on-package memory controller circuitry. The on-package memory controller circuitry is disposed below the memory stack. The redistribution layer electrically couples circuitry of the logic device with circuitry of the active silicon bridge.

In yet another example, an electronic device is provided. The electronic device includes chip package as described herein mounted to a printed circuit board (PCB).

In some examples, the active silicon bridge of the electronic device further includes a physical interface layer configured to communicate with the logic device and memory controller circuitry coupled to the first and second physical interface layers.

In some examples, the memory controller circuitry further includes off-package memory controller circuitry and on-package memory controller circuitry. The electronic device may also include off-package memory coupled to the PCB. The off-package memory is communicatively coupled to the off-package memory controller circuitry.

In some examples, the off-package memory is volatile memory. In some examples, the off-package memory is double data rate synchronous dynamic random-access memory (DDR SDRAM).

In some examples, the active silicon bridge is bounded to either side by mold compound. In some examples, the active silicon bridge is disposed in a cavity formed in an interposer. In yet other examples, the active silicon bridge is an interposer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of one example of a chip package having a silicon bridge, a logic device and memory stack that can be incorporated in an electronic device.

FIG. 2A is an enlarged partial schematic sectional view of one example of a portion of the chip package of FIG. 1 illustrating the interface between the memory stack, the logic device, and the silicon bridges.

FIG. 2B is an enlarged partial schematic sectional view of another example of a portion of the chip package of FIG. 1 illustrating the interface between the memory stack, the logic device, and the silicon bridges.

FIG. 2C is an enlarged partial schematic sectional view of another example of a portion of the chip package of FIG. 1 illustrating the interface between the memory stack, the logic device, and the silicon bridges.

FIG. 3 is a schematic sectional view of another example of a chip package having a silicon bridge, a logic device and memory stack that can be incorporated in the electronic device of FIG. 1.

FIG. 4 is a schematic sectional view of another example of a chip package having a silicon bridge, a logic device and memory stack that can be incorporated in the electronic device of FIG. 1.

FIG. 5 is a schematic plan view of the chip package of FIG. 1.

FIG. 6 is a schematic plan view of another variation of a chip package that can be incorporated in the electronic device of FIG. 1.

FIG. 7 is a schematic block diagram of illustrating on example of an active interposer die of a logic device interfaced with memory stacks and logic devices that can be incorporated in the chip package of FIG. 1.

FIGS. 8-10 are schematic plan views of different configurations of a logic device illustrating exemplary compute die stacks that can be incorporated in the chip package of FIG. 1.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Disclosed herein are chip packages and electronic devices that utilize passive and/or active silicon bridges to provide a signal interface between a logic device having at least one compute die and one or more memory stacks or other logic device within a singular chip package. The active silicon bridge may include one or more IP blocks, such as a memory controller. The silicon bridges have many metal layers for die to die connections, and may optionally include through silicon vias (TSVs) for vertical connections to the substrate. Passive silicon bridges 110 include passive devices, such as capacitors, inductors, and resistors, among others. Silicon bridges may have decoupling capacitors, for example deep trench capacitors, such as metal insulator metal (MIM) capacitors. The chip packages leverage a 2.5D/3D architecture where one or more silicon bridges are used for lateral die-to-die connections, and optionally include functional circuitry formed in a physical layer (PHY). In some example, the functional circuitry formed in a physical layer (PHY) may be configured as a universal chiplet interconnect express (UCIe) PHY, thus enabling the transistors needed for die-to-die connection in the PHY to be relocated from the connected compute die, such as an CPU/GPU SOC, to the silicon bridge.

The silicon bridge architecture enables efficient multiple levels of integrated circuit (IC) compute dies stacked to form a logic device. Performance may be further gained through the use of hybrid bonding between the IC compute dies of the logic device. Active interposers further enable multiple stacks of compute dies within a single logic device. The compute dies may be configured as CPUs and/or GPUs as needed to provide flexibility between package configurations.

The silicon bridge architecture enables the logic device to be efficiently connected to one or more adjacent memory stacks and/or an input/output (I/O) die. In some examples, one or more silicon bridges may optionally extend below both the logic device and at least one memory stack to efficiently position die-to-die PHY (such as UCIe) for improved performance and lower overall costs. The silicon bridge architecture may optionally include external I/O PHY (DDR, PCIe, etc.) in a location close to the package substrate that reduces routing congestion. The silicon bridge architecture may alternatively be utilized to efficiently connect two logic devices in close proximity within the chip package to reduce routing congestion and improve performance.

In some examples, the silicon bridge architecture also improves logic device yield by moving the analog PHY out of the logic device and into the silicon bridge. The silicon bridge architecture also avoids need for custom memory stacks by including off-package memory PHYs in the active silicon bridge. Since the silicon bridge may be more cost effectively produced relative to other components (e.g., IC dies) of the chip package, standard chiplet designs may be used across a greater number of chip package configurations. Moreover, the modular arrangement of the silicon bridge, memory stacks and logic device makes the chip package readily scalable and customizable without the need for additional tapeouts. The number and position of the modular arrangement components of the chip package may be selected and arranged for various compute applications without the need for new die or interposer designs. As a result, the chip package provides increased application flexibility at reduced manufacturing costs.

In some examples, the silicon bridge generally includes memory controller circuitry disposed below the memory stack. The location of the memory controller circuitry below the memory stack shortens routing, allowing improved transmission speeds and lower power consumption. Furthermore, each silicon bridge may be configured to interface with one or more memory stacks and one or more compute dies of the logic devices more efficiently as compared to conventional chip packages, resulting in a scalable, robust, and cost efficient design.

In one example, a chip package is provided that includes a substrate, a silicon bridge, a logic device, and a memory stack. The logic device and the memory stack are mounted over the substrate. The logic device is communicatively coupled to the memory stack via the silicon bridge that may be mounted above or below the logic device and the memory stack. The silicon bridge may include deep trench capacitors.

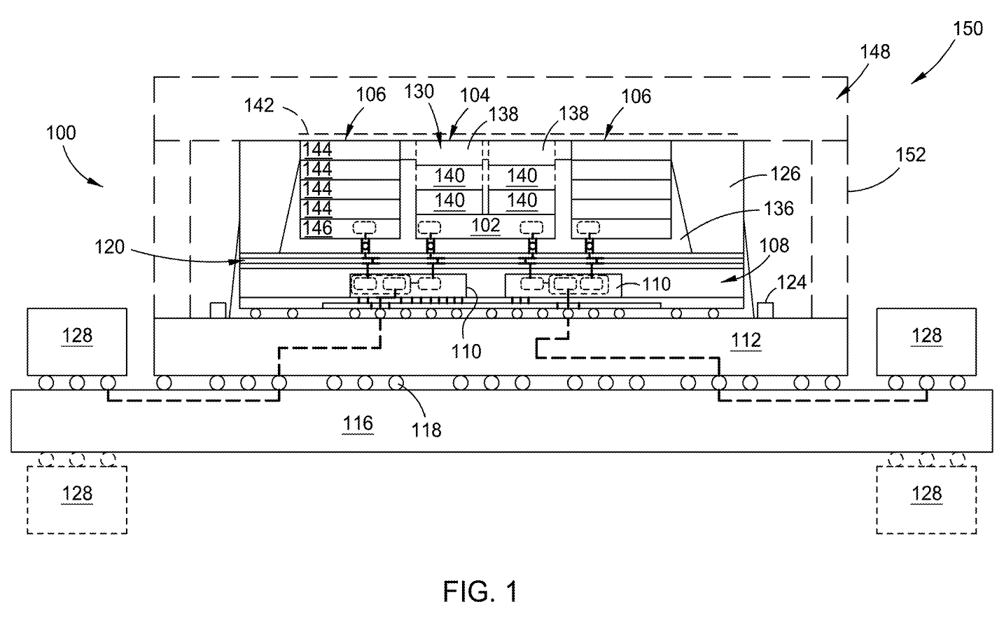

Turning now to FIG. 1, a schematic sectional view of one example of a chip package 100 is provided. The chip package 100 is shown mounted to a printed circuit board (PCB) 116 to form an electronic device 150. The chip package 100 may be configured to mate with corresponding pins of a socket mounted on the PCB 116 to form the electronic device 150. Alternatively and as illustrated in FIG. 1, solder balls 118 may be used to connect the exposed bond pads on the bottom surface of the package substrate 112 to the PCB 116 to form the electronic device 150.

The PCB 116 may optionally have one or more memory devices 128 that are mounted to the PCB 116. Memory devices 128 are shown are mounted to the top surface the PCB 116 in FIG. 1. However, memory devices 128 may also be additionally or alternatively mounted to the bottom surface the PCB 116. The memory device 128 may include one or more memory dies configured as volatile and/or non-volatile memory. In one example, the memory device 128 includes at least one memory die configured as volatile memory. One example of volatile memory is double data rate synchronous dynamic random-access memory (DDR SDRAM). In other examples, the memory devices 128 may be located remote from the electronic device, but can be assessed by components of the chip package 100 by signal transmission routed though the PCB 128 to the chip package 100.

The chip package 100 includes at least one silicon bridge 110, at least one logic device 104, and at least one memory stack 106. The at least one memory stack 106 may alternatively be a second logic device 104. The silicon bridge 110 provides on package communication between the logic device 104 and the memory stack 106 (and/or second logic device 104). Although only one silicon bridge 110 is illustrated in FIG. 1, two or more silicon bridges 110 may be present in a common layer below the logic device 104. The silicon bridge 110 may include passive and/or active circuitry, as further described below. The logic device 104 includes at least one compute die 140, which includes logic circuitry. Although two logic devices 104 are illustrated in FIG. 1, the chip package 100 may include one to as many logic devices 104 as space permits to achieve desired functionality. Similarly, the chip package 100 illustrated in FIG. 1 may include one to as many memory stacks 106 as space permits to achieve desired functionality.

The memory stack 106 includes a buffer die 146 having one or more memory dies 144 stacked thereon. The memory stack 106 is generally mounted adjacent the logic device 104. Each memory stack 106 is generally connected with the adjacent logic device 104 via the silicon bridge 110. In some examples, more than one memory stack 106 may be connected with a common adjacent logic device 104 via a single silicon bridge 110 or multiple silicon bridges 110.

In the exampled depicted in FIG. 1, one or more memory stacks 106 are directly connected to the adjacent logic device 104 via a high bandwidth routing formed in the silicon bridge 110. The silicon bridge 110 may be disposed above or below the one or memory stack 106, and in one example, is disposed in the interposer layer 108 residing below the connected memory stack 106 and logic device 104.

As discussed above, each of the memory stacks 106 includes a plurality of stacked memory dies 144. Using the plane of the package substrate 112 as a horizontal reference, the memory dies 144 are vertically stacked. The memory dies 144 within each memory stack 106 can be interconnect via solder interconnect, via hybrid bonding, or other suitable technique. The memory dies 144 within a common memory stack 106 may be volatile memory, such as static random-access memory (SRAM), dynamic random-access memory (DRAM) or other suitable volatile memory type. Optionally, one or more of the memory dies 144 within a common memory stack 106 may be non-volatile memory, such as ferroelectric random-access memory (FeRAM) and magnetoresistive random-access memory (MRAM) or other suitable non-volatile memory type. The memory types of the memory dies 144 of one memory stack 106 may be the same or different than the memory types of the memory dies 144 of another memory stack 106 adjacent a common logic device 104, or another memory stack 106 disposed in another region of the chip package 100 and adjacent a different logic device 104 of the chip package 100.

The number of memory dies 144 within common memory stack 106 may range from 2 to as many as desired. In one example, the number of memory dies 144 within common memory stack 106 is 4 to about 16. The number of memory dies 144 within different memory stacks 106 of the chip package 100 typically are the same. However, memory stacks 106 having different numbers of memory dies 144 may be utilized. When memory stacks 106 having different numbers of memory dies 144 are utilized, the memory stacks 106 may be configured to have the same height. For example, the height difference between stacks 106 may be compensated for by using memory dies 144 having different thicknesses and/or the use of one or more dummy dies on top of the memory stack 106.

The buffer die 146 is generally located at the bottom of the memory stack 106, between the memory dies 144 and the package substrate 112. The buffer die 146 includes I/O circuitry. In another example, the buffer die 146 of the memory die stack 106 may also include a volatile or non-volatile memory circuitry. The buffer die 146 can be interconnect with the overlying memory die 144 via solder interconnect, via hybrid bonding, or other suitable technique.

The logic device 104 includes at least one compute die 140, which may optionally be arranged in one or more compute die stacks 130. When more than one compute die stacks 130 are used in a common logic device 104, the die stacks 130 are mounted on a common IC interposer die 102. In the example depicted in FIG. 1, two compute die stacks 130 are shown. However, additional compute die stacks 130 may be present in a single chip package 100. Each compute die stack 130 includes at least one compute die 140. In the example depicted in FIG. 1, each compute die stack 130 include a two or more compute dies 140.

Compute dies 140 within a common compute die stack 130 may be the same type of die or a different type of processor die. The compute dies 140 within a compute die stack 130 of one logic device 104 of the chip package 100 may be the same type of processor die or a different type of processor die than a compute die 140 in another compute die stack 130 included in the same logic device 104. Similarly, compute dies 140 within one logic device 104 of the chip package 100 may be the same type of processor die or a different type of processor die than another compute die 140 included in another logic device 104 included in the same chip package 100.

The compute dies 140 are electrically and mechanically coupled to the IC interposer die 102 by interconnects, such as solder bumps, hybrid bonding, or other suitable technique. In the example depicted in FIG. 1, the compute die 140 is hybrid bonded to the IC interposer die 102. Similarly, the compute die 140 is electrically and mechanically coupled to the adjacent compute die 140 in the compute die stack 130 by interconnects, such as solder bumps, hybrid bonding, or other suitable technique. In the example depicted in FIG. 1, the compute dies 140 are hybrid bonded together. As discussed above, hybrid bonded desirably improves communication speeds and allows for increased bandwidth. Moreover, hybrid bonding allows for compute dies having different configurations of bond pad locations to be mounted on the same IC interposer die design since the bond pad in the hybrid bonding layer may be easily relocated without need for a different IC interposer die.

In one example, the functional circuitry of all of the compute dies 140 within a common logic device 104 include central processing unit (CPU) cores. As such, each of the compute dies 140 may be referred to as a CPU die or CPU chiplet. The functional circuitry of the compute dies 140 may also include System Management Unit (SMU). The SMU is circuitry configured to monitor thermal and power conditions and adjust power and cooling to keep the dies 140 functioning as within specifications. The functional circuitry of the compute dies 140 may also include Dynamic Function eXchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition.

In another example, the functional circuitry of all of the compute dies 140 within a common logic device 104 include accelerated compute cores. As such, each of the compute dies 140 may be referred to as an accelerator die or accelerator chiplet. The compute dies 140 may also be referred to as a graphic processing unit (GPU) die or GPU chiplet. The accelerated compute cores contained in the functional circuitry of the compute dies 140 generally includes math engine circuitry. The math engine circuitry is generally designed for task specific computing, such as used data center computing, high performance computing and AI/ML computing. Along with the accelerated compute cores, functional circuitry of the compute die 140 may also include SMU circuitry and DFX circuitry.

In other examples, the functional circuitry of at least two of the compute dies 140 within a common logic device 104 are different. For example, one compute die 140 may include accelerated compute cores, while another compute die 140 within a common logic device 104 includes CPU cores. In another example, one or more compute dies 140 present in a common compute die stack 130 may include CPU cores and/or an accelerated compute cores. In yet another example, one or more compute dies 140 present in a first compute die stack 130 may include CPU cores and/or an accelerated compute cores, while one or more compute dies 140 present in a second compute die stack 130 within a common logic device 104 may include CPU cores and/or an accelerated compute cores, wherein the types of compute dies 140 within the first and second compute die stacks 130 may have the same or different arrangement of compute die types.

The logic device 104 may additionally include a carrier die 138 disposed over the compute die stacks 130. The carrier die 138 generally is the top die in the logic device 104, located farthest from the package substrate 112. The carrier die 138 is generally a block of silicon material that provides good heat transfer out of the logic device 104. The carrier die 138 may be thicker than the compute dies 140, thus providing increased structural rigidity and increase resistance to warpage within the logic device 104, which makes connections between compute dies 140 more reliable and robust. The carrier die 138 may be circuit free, i.e., free from routing, passive and active circuit devices. The carrier die 138 is adhered to one or both of the compute die stacks 130. The carrier die 138 may be adhered to the compute die(s) using any suitable adhesive or technique. In one example, the carrier die 138 is fusion bonded to the compute die(s). In such an example, an oxide layer is disposed between the carrier die 138 and the compute die(s) to enhance the fusion bonding process. Fusion bonding increases the structural rigidity of the logic device 104, and makes connections between compute dies 140 more reliable and robust. Optionally, a single carrier die 138 may span more than one logic device 104.

The logic device 104 may additionally include a dummy die (not shown) disposed over or next to one or more of the compute dies 140. The dummy die generally is between the carrier die 138 and the IC interposer die 102. The dummy die may alternatively contact one of the carrier die 138 and the IC interposer die 102, and also contact one or more of the compute dies 140. The dummy die is generally a block of silicon material that provides good heat transfer through the logic device 104. The dummy die also provide mechanical stability across the width of the logic device 104. The dummy die may be circuit free, i.e., free from routing, passive and active circuit devices. The dummy die is adhered to the overlying and underlying dies (i.e., two of the compute dies 140, IC interposer die 102, and carrier die 138. The dummy die may be adhered to the neighboring overlying and underlying dies using any suitable adhesive or technique. In one example, the dummy die is fusion bonded to the neighboring overlying and underlying dies. In such an example, an oxide layer is disposed between the dummy die and each of the neighboring overlying and underlying dies to enhance the fusion bonding process. As with the carrier die 138, fusion bonding of the dummy die increases the structural rigidity of the logic device 104, and makes connections between compute dies 140 more reliable and robust. Optionally, more than one dummy die may be used in a single logic device 104.

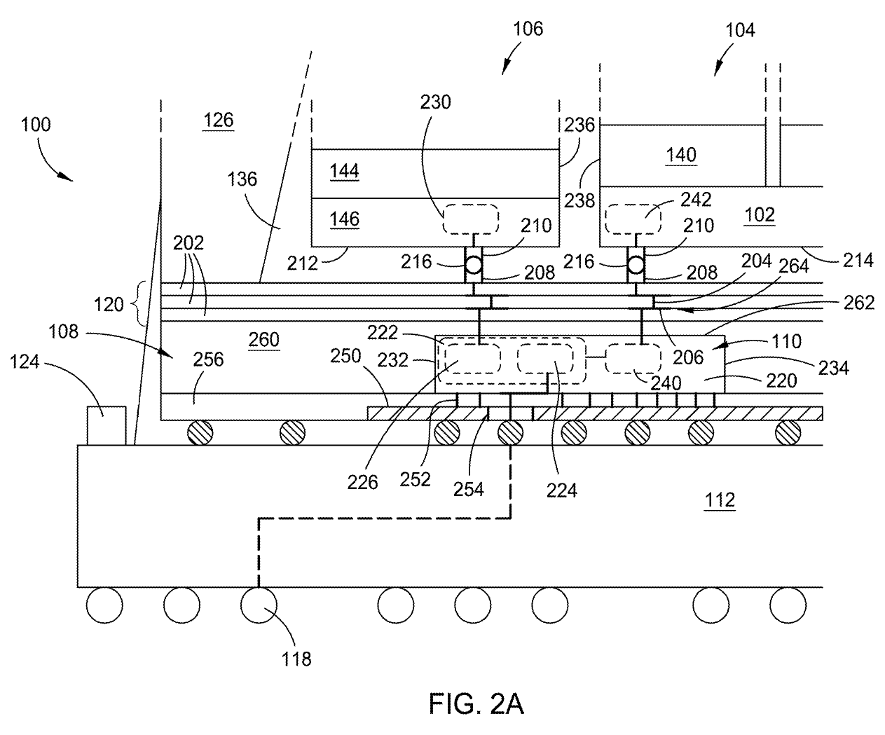

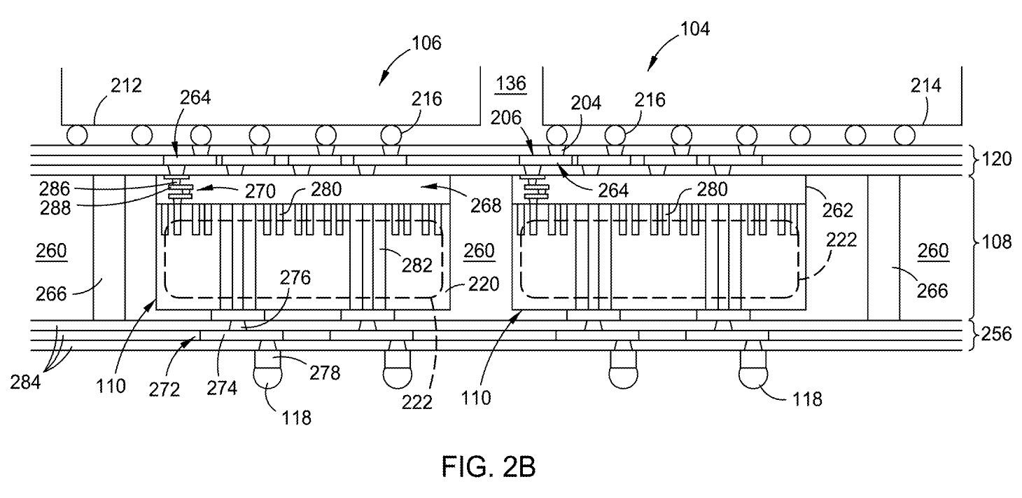

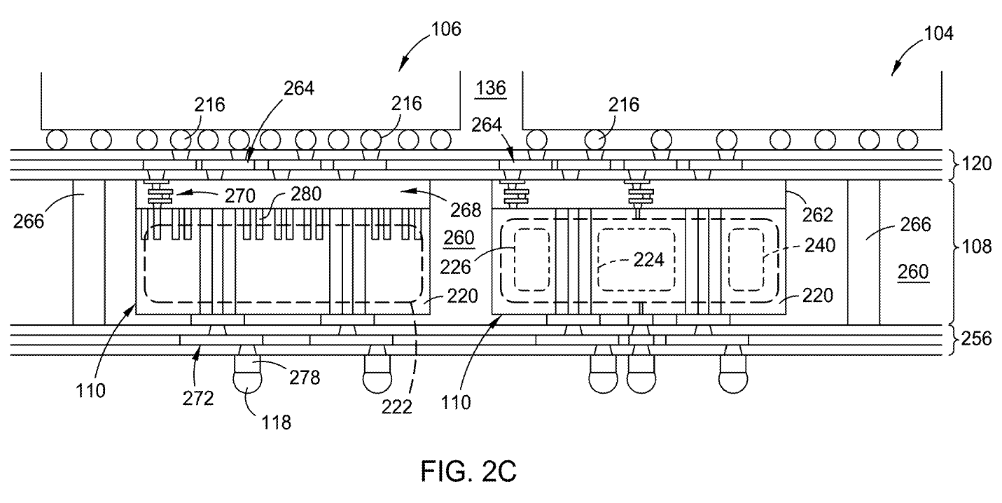

The memory stack 106 and the logic device 104 are disposed above a common package substrate 112. An interposer layer 108 is disposed on and electrically connected to the package substrate 112. The silicon bridge 110 comprises or resides in the interposer layer 108. The memory stack 106 and the IC interposer die 102 are electrically and mechanically coupled to the interposer layer 108 via an interconnect interface 114. The interconnect interface 114 may include any one or more of solder bumps, hybrid bonding, and a redistribution layer or other type of routing fanout. In the example depicted in FIG. 1, the interconnect interface 114 includes a redistribution layer 120. The redistribution layer 120 is further detailed in FIG. 2A.

Continuing to refer to FIG. 1, underfill material 136 may be disposed below the memory stack 106 and the logic device 104 to protect electrical connections and to provide structural strength. Additionally, mold compound 126 may be disposed around the memory stack 106 and the logic device 104. The mold compound 126 provides structural rigidity to the chip package 100, improving warpage resistance while also protecting the electrical components of the chip package 100. The top surfaces of the memory stack 106 and the logic device 104 may be exposed through the mold compound 126 to facilitate interfacing with a thermal management device 148 (shown in phantom), such as a lid, a heat sink, heat pipe, phase change material, thermal interface material (including liquid metal thermal interface materials), heat spreaders, liquid cooling places, and/or thermal electric cooling plates, among others. The thermal management device 148 may be secured to the package substrate 112 or PCB 116 using fasteners, spring pins, clips, clamps or other suitable device. In the example depicted in FIG. 1, the thermal management device 148 is connected to a stiffening ring 152 (also shown in phantom) that is mounted to the perimeter of the package substrate 112.

The top surfaces of the mold compound 126, the memory stack 106, and the compute die stack 130 may optionally be covered by a metal layer 142 to enhance heat transfer to thermal management device 148. The metal layer 142 may be copper, aluminum, nickel, other suitable material. A thermal interface material (TIM (not shown)) may be disposed between and in contact with the metal layer 142 and underside of thermal management device 148. The TIM may be a liquid metal, graphite, graphene, phase change material, thermal grease, thermal pad, or other suitable heat transfer material. In one example, the TIM is indium.

Referring now to both FIGS. 1 and 2A, the redistribution layer 120 includes routing the electrically connects routing of the interposer layer 108 (which also includes circuitry of the silicon bridge 110) to the circuitry of the logic device 104 and the memory stack 106. The redistribution layer 120 include a plurality of dielectric layers 202 in which the routing circuitry of the redistribution layer 120 is formed. The routing circuitry of the redistribution layer 120 includes routing circuitry 264 formed from patterned conductive lines 206 connected by vias 204. Not all the routing circuitry 264 of the redistribution layer 120 is shown in FIGS. 1 and 2A to avoid overcrowding the illustrations.

The routing circuitry of the redistribution layer 120 is terminated at an upper end at conductive pillars 208. The conductive pillars 208 may be plated copper or other suitable material. Some of the conductive pillars 208 are connected to conductive pillars 210 formed below and in contact with the conductive pads (not shown) exposed on a bottom surface 214 of the logic device 104 and a bottom surface 212 of the memory stack 106. The pillars 208, 210 are electrically connected by interconnects 216, such as solder microbumps, hybrid bonds, or other suitable technique. Some of routing circuitry of the redistribution layer 120 terminates at a lower end at the conductive pads (not shown) formed on an upper surface of the silicon bridge 110. Thus, signals may be transferred between the logic device 104 and the silicon bridge 110 via some of routing circuitry of the redistribution layer 120. Signals may be also transferred between the memory stack 106 and the silicon bridge 110 via other portions of routing circuitry of the redistribution layer 120.

Referring now primarily to FIG. 2A, outer sides 232, 234 of the silicon bridge 110 horizontally overlaps facing sides 236, 236 the logic device 104 and the memory stack 106. Alternatively, the outer sides 232, 234 of the silicon bridge 110 may horizontally overlap only one or none of facing sides 236, 236 the logic device 104 and the memory stack 106. The silicon bridge 110 is generally a chiplet having a body 220 that contains circuitry 222. The body 220 is generally a block of silicon material upon which the circuitry 222 is formed. In one example, the circuitry 222 includes high bandwidth routing for coupling the circuitries of the memory stack 106 and the logic device 104. The body 220 also may include through silicon vias for routing ground, power and/or signals from the underside of the silicon bridge 110. In the example depicted in FIG. 2A, the silicon bridge 110 is active device, and the circuitry 222 of the advice device may include one or more intellectual property cores (e.g., IP blocks). The IP blocks may include one or more IP blocks 222 selected from the group consisting of Serializer/Deserializers (SerDes), phase-locked loops or phase lock loops (PLLs), digital-to-analog converters (DACs), analog-to-digital converters (ADCs), physical layers (PHYs), central processor units CPUs, direct memory access (DMA) engines, accelerators, and memory controllers, integrated voltage regulators (IVRs), among others. In the example depicted in FIG. 2A, the IP block comprising the functional circuitry 222 is a memory controller circuitry (also referred to herein as memory controller circuitry 222). The memory controller circuitry 222 includes off-package memory controller circuitry 224 and on-package memory controller circuitry 226. The off-package memory controller circuitry 224 is generally configured to control communications with memory that is not within (e.g., remote from) the chip package 100. The off-package memory controller circuitry 224 is configured to communicate with memory located within the electronic device 150 that are not within the chip package 100, or with memory located outside of the electronic device 150. In one example, the off-package memory controller circuitry 224 is configured to communicate through the package substrate 112 with the one or more memory devices 128 that are mounted to the PCB 116; or stated differently, memory devices that are located within the electronic device 150 but are not within the chip package 100.

Continuing to refer to FIG. 2A, the on-package memory controller circuitry 226 is located in the silicon bridge 110 below the memory stack 106. In one example, the on-package memory controller circuitry 226 is directly below the memory stack 106. The buffer die 146 of the memory stack 106 includes I/O circuitry 230. The I/O circuitry 230 overlies a portion of the silicon bridge 110 that includes the on-package memory controller circuitry 226. The on-package memory controller circuitry 226 is also below the memory stack 106. As the I/O circuitry 230 of the buffer die 146 of the memory stack 106 is substantially vertically aligned the on-package memory controller circuitry 226.

In one example, the memory controller circuitry 222 includes one or more of interconnect circuitry, high bandwidth memory attached last level cache (HALL) circuitry, tag circuitry, memory circuitry, memory controller circuitry, memory devices, and direct memory access (DMA) circuitry. The silicon bridge 110 may include coherency station circuitry that includes N coherency station circuitries. The HALL circuitry includes N HALL circuitries, the tag circuitry includes N tag circuitries, and the memory controller circuitry includes N memory controller circuitries. N is greater than 1. In one example, N is 2, 4, or 8, or more. In one example, each memory die 144 is associated with a respective memory controller circuitry, a respective HALL circuitry, and a respective tag circuitry.

The memory circuitry 222 includes the arbitration circuitry, and memory controller circuitry. In one example, the memory circuitry 222 includes more than one arbitration circuitry and/or more than one memory controller circuitry.

In some examples, the memory controller circuitry 222 includes a cache memory. In such an example, local copies of data stored within the memory dies 144 are stored within the cache memory. The tag circuitry maintains tags that associate memory lines and data stored within the memory dies 144 to addresses (e.g., memory lines) within the memory die 144. In one example, the tag circuitry is a static random access memory (SRAM), or another type of memory. As data within the memory die 144 is accessed, copies of the data are stored within a memory die 144 via a respective HALL circuitry and a respective memory controller circuitry. Further, a tag is updated or created within a respective tag circuitry to associate the address (or memory line(s)) of the data within the memory die 144 to the memory address (memory lines) of the data within the external memory device 128. Accordingly, when future memory commands are used to access the memory address, the memory command is forwarded to the memory dies 144 to retrieve the data. As the memory dies 144 have a higher bandwidth than the memory device 128, reading data from the memory dies 144 is faster, increasing the operating speed and decreasing lag of the corresponding system (e.g., the chip package 100 of FIG. 1).

In one example, a read memory command for a first address is provided by the coherency station circuitry and is received by the HALL circuitry. The HALL circuitry accesses the tag circuitry to determine if data associated with the first address is stored within a memory die 144. If a tag within the tag circuitry indicates that the data associated with the first address is stored within a memory die 144, a “hit” is declared and the memory lines of the corresponding memory device 280 is read and the data is output. If a tag within the tag circuitry indicates that the data associated with the first address is not stored within a memory die 144, a “miss” is declared and the read command is provided to the arbitration circuitry, and the memory controller circuitry to access to the memory device 128. The memory line(s) of the memory device 128 associated with the address of the memory command is accessed, and the corresponding data is output to the logic device 104 via the coherency station circuitry. In one example, the data is further stored within one of the memory dies 144, and a corresponding tag within the tag circuitry is updated via the HALL circuitry.

For a write command, the coherency station circuitry provides the write command including an address and data to the HALL circuitry via the interconnection circuitries. The HALL circuitry uses the tags within tag circuitry to determine if the address of the write command is within the memory dies 144. If the address of the write command is associated with an address (e.g., memory lines) of the memory dies 144 (e.g., a “hit”) the data is written to the memory die 144 via the associated address. The data may be written to the corresponding address within the memory device 128 at a later point, reducing latency in the corresponding system. If the address of the write command is determined to not be associated with an address of the memory dies 144 (e.g., a “miss”), the write command is provided to the arbitration circuitry, and the memory controller circuitry to be written to the corresponding memory lines of the external memory device 128. In one example, the memory address of the write memory command and corresponding data is additionally loaded into the memory dies 144 and a tag within the tag circuitry is updated via the HALL circuitry. Accordingly, future access to the requested memory address is sped up as the bandwidth and speed of the memory die 144 is greater than that of the memory device 128. In one or more examples, instead of directly writing to the external memory device 128, when a miss is determined, the memory line(s) of the external memory device 128 associated with the write command is (are) loaded into the memory die(s) 144 and the tags within the tag circuitry is updated. The data of the write command is written to the corresponding memory lines of the memory device(s). In one example, during a write memory command, the data is written to the memory die 144 and a corresponding tag within the TAG circuitry is updated, and an indication is provided to the memory device 128, alerting the memory device 128 to a write to an address within the memory device 128. The memory controller circuitry and/or the memory device 128 may prevent a write or read to the same address until the write command is completed by writing the data from the memory dies 144 to the memory device 128.

In one example, the memory controller circuitry 222 provides one or more memory commands (e.g., read and/or write commands) to the DMA circuitry. The memory commands are provided as pre-fetched, predicted, preliminary, pending, or future memory commands. For example, the on-package memory controller circuitry 226 determines pre-fetched memory commands based on an application executing within the processing circuitry. The pre-fetched memory commands are provided the DMA circuitry before the executed application generates the memory commands. The DMA circuitry and HALL circuitry determines whether or not the addresses and data associated with the predicted memory commands are stored within the memory dies 144 via the tags of the tag circuitry. For addresses that are not found within the memory dies 144, the DMA circuitry, the memory controller circuitry, and the HALL circuitry provide the corresponding memory commands to the memory controller and the memory device 128, to load the corresponding data into memory lines of the memory dies 144. For data that is loaded from the memory device 128 to the memory dies 144, a corresponding tag within the tag circuitry is updated, mapping the memory lines (e.g., memory addresses) of the memory dies 144 to memory lines (e.g., memory addresses) of the memory device 128. Accordingly, when the application running on the memory controller circuitry 222 executes a memory command, the data and address of the memory command is accessible within the memory dies 144, reducing latency and speeding up operation of the corresponding system. In one example, the memory commands provided to the memory controller circuitry and the memory device 128 are scheduled when bandwidth is available within the memory dies 144, further reducing latency within the corresponding computer system, and increasing the speed of the corresponding computer system.

Similarly, the silicon bridge 110 includes a physical interface layer (PHY) 240 configured to communicate with a physical interface layer 242 of the logic device 104. The physical interface layer 240 is overlapped with the logic device 104. The physical interface layer 242 is overlapped with a portion of the silicon bridge 110 that is under the logic device. As the physical interface layers 240, 242 are essentially vertically aligned, less space is need for routing, while the short routing distance also improves communication speed and performance.

The chip package 100 may also include an optional metal layer 250 disposed between the silicon bridge 110 and the package substrate 112. The metal layer 250 may be electrically isolated from the silicon bridge 110 by a dielectric layer 256. The metal layer 250 extends beyond one or both sides 232, 234 of the silicon bridge 110. The metal layer 250 functions to route heat generated by the silicon bridge 110 or other routing below the silicon bridge 110 laterally outward from below the silicon bridge 110. As such, the metal layer 250 is not part of the shielding, ground, power or signal transmission circuitry of the chip package 100. Thermal vias 252 formed through the dielectric layer 256 may be utilized to conduct heat from the bottom surface of the silicon bridge 110 to the metal layer 250. Routing heat laterally away from the silicon bridge 110 improves the performance and reliability of the functional circuitry residing within the silicon bridge 110.

The metal layer 250 and dielectric layer 256 also include apertures 254 formed therethrough that allow ground, power and/or signal transmission circuitry to be routed through the metal layer 250 between the circuitry of the package substrate 112 to the circuitry of the silicon bridge 110. In one example, signal routing passes through apertures 254 formed through the metal layer 250 to connect to the memory devices 128 disposed on the PCB 116. In another example, power routing passes through apertures 254 formed through the metal layer 250 to power to the functional circuitry residing within the silicon bridge 110.

In the example depicted in FIGS. 1 and 2A, the silicon bridge 110 is disposed in a layer of mold compound 260. The mold compound 260 may be an epoxy, polymer, or other suitable dielectric material. The silicon bridge 110 is disposed in a cavity 262 formed in the mold compound 260, or may be fully or partially encapsulated in the mold compound 260.

FIG. 2B is an enlarged partial schematic sectional view of another example of a portion of the chip package 100 of FIG. 1 illustrating the interface between the memory stack 106, the logic device 104, and the silicon bridges 110. An example depicted in FIG. 2B, two silicon bridges 110 are shown. However, one, three or more two silicon bridges 110 may be utilized. Also in the embodiment depicted in FIG. 2B, the silicon bridges 110 are depicted as passive devices. For example, the functional circuitry 222 of the silicon bridges 110 may include high bandwidth routing for coupling the circuitries of the memory stack 106 and the logic device 104. In another example, the functional circuitry 222 of the silicon bridges 110 may additionally or alternatively include passive devices, such as capacitors, inductors, and resistors, among others. In one example, the circuitry 222 of the silicon bridges 110 include decoupling capacitors. The decoupling capacitors comprising the circuitry 222 of the silicon bridges 110 may be deep trench capacitors, such as metal insulator metal (MIM) capacitors, metal-oxide-semiconductor (MOS) capacitors, among others. The decoupling capacitors comprising the circuitry 222 of the silicon bridges 110 may be part of a power delivery network coupled to the logic device 104.

The body 220 also may include through silicon vias 282 for routing ground, power and/or signals vertically through of the silicon bridge 110. Silicon vias 282 may also be present in the body 220 of the embodiment illustrated in FIG. 2A. The silicon vias 282 may optionally be coupled to the functional circuitry 222 of the silicon bridge 110. The silicon vias 282 generally connect routing circuitry 272 formed in the dielectric layers 256 disposed at the bottom of the interposer 108 with routing circuitry 270 formed in a build-up layer 268 that fills the space between the top surface of the silicon bridge 110 and the top surface of the interposer 108.

The routing circuitry 272 is formed from patterned conductive lines 274 connected by vias 276 within one or more layers of dielectric material 284, similar to that circuitry 264 of RDL 120. The routing circuitry 272 terminates at a pillar 278 on which the solder interconnect 118 is formed. Similarly, the routing circuitry 270 formed in a build-up layer 268 is also formed from patterned conductive lines 288 connected by vias 286 within one or more layers of dielectric material, similar to that circuitry 264 of RDL 120. The routing circuitry 270 terminates at the bottom surface of the RDL 120, where the routing circuitry 270 is electrically connected with the circuitry 264 of RDL 120.

Optionally, one or more conductive pillars 266 may be disposed through the mold compound 260. Optionally, one or more of the conductive pillars 266 may be electrically floating or grounded, and used as a thermal via for conducting heat out of the chip package 100. Optionally, one or more of the conductive pillars 266 may be electrically connected with the circuitries 264, 272 of the RDL 120 and the dielectric layer 256, and used to conduct at least one or more of ground, power and/or data signals. The conductive pillars 266 may also be present extending through the mold compound 260 of the embodiment illustrated in FIG. 2A.

FIG. 2C is an enlarged partial schematic sectional view of another example of a portion of the chip package 100 of FIG. 1 illustrating the interface between the memory stack 108, the logic device 104, and at least two silicon bridges 110. In the example depicted in FIG. 2C, at least one of the silicon bridges 110 includes active devices, such as described with reference to FIG. 2A, and at least one of the silicon bridges 110 includes passive devices, such as described with reference to FIG. 2B. In one example, the active device of the circuitry 222 of one silicon bridge 110 may be configured as an integrated voltage regulator that is coupled with the passive device of the circuitry 222 of another silicon bridge 110 that is configured as decoupling capacitors.

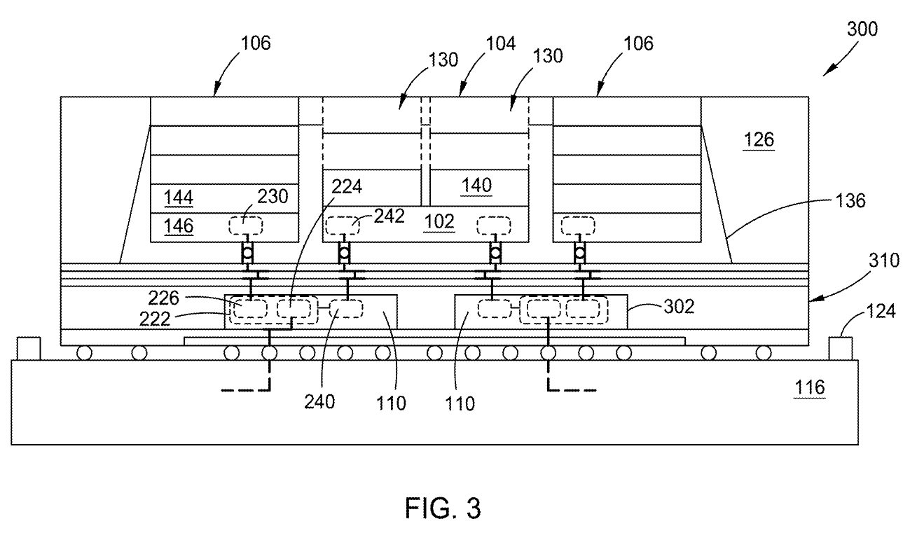

Alternatively as illustrated in another configuration of a chip package 300 depicted in FIG. 3, the silicon bridge 110 of any of the examples discussed above or similarly constituted, may be disposed in a cavity 302 formed in an interposer 310. The interposer 310 may be formed from a plastic material, glass reinforced plastic, ceramic, glass or other suitable dielectric material. The other components of the chip package 300 are substantially the same as the chip package 100 described above.

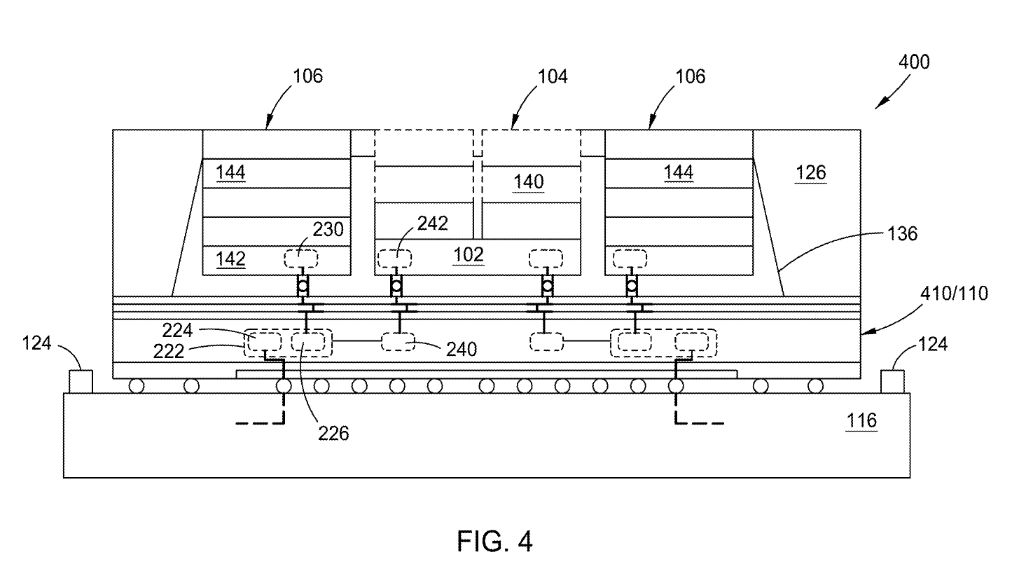

Alternatively as illustrated in another chip package 400 depicted in FIG. 4, the silicon bridge 110 be configured as an interposer 410. The interposer 410 includes the circuitry of the silicon bridge 110. Thus, the interposer 410 may be configured as a large silicon die. The other components of the chip package 400 are substantially the same as the chip package 100 described above.

Referring back to FIG. 1, the package substrate 112 may also include surface mounted components 124 that are coupled to the logic device 104 via routing formed through the package substrate 112, the interposer layer 108, the interconnect interface 114, and/or the silicon bridge 110. The surface mounted components 124 may be integrated passive devices (IPDs), such as capacitors, inductors, and resistors, among others. In one example, the surface mounted components 124 are capacitors. In addition or alternatively, some or all of the surface mounted components 124 may be located as IPDs in other locations of the chip package 100. For example, IPDs may be located within or attached to the interposer layer 108, within the package substrate 112, in the redistribution layer 120, or other suitable location within the chip package 100

The package substrate 112 may include an optional stiffener (not shown). The stiffener, when present, has a ring shape surrounds the memory stack 106 and the logic device 104, and the surface mounted components 124. The stiffener may be affixed to the top surface of the package substrate 112, thus making the package substrate 112 and ultimately the chip package 100 less prone to warpage, improving the reliability and performance of the chip package 100.

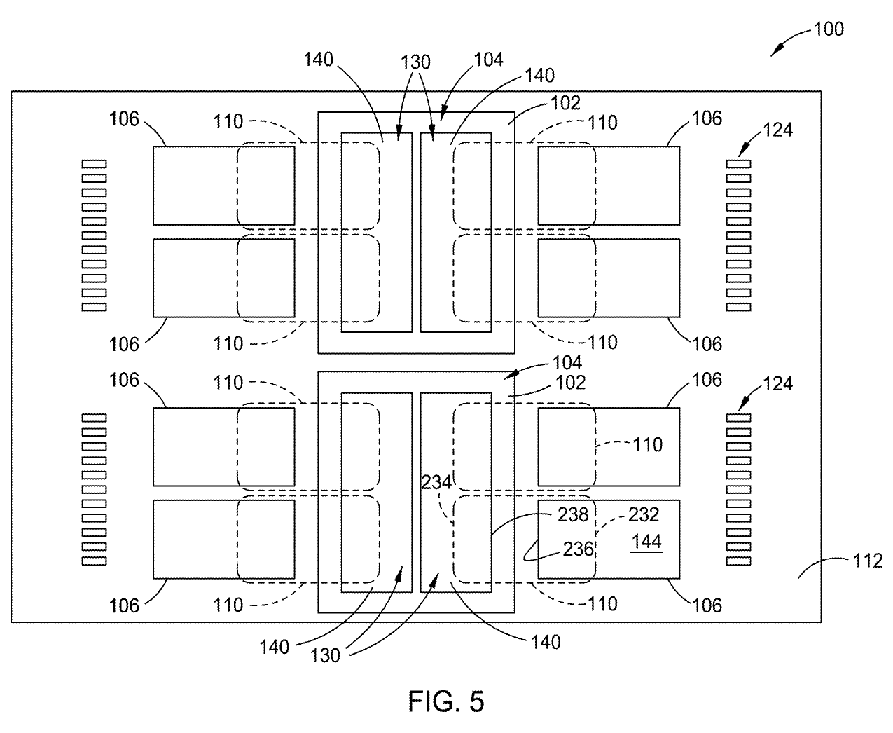

As discussed above, one or more silicon bridges 110 may be interfaced with one or more logic devices 104. In the top view of the chip package 100 depicted in FIG. 5, each silicon bridge 110 (shown in phantom) is interfaced with one logic device 104. Each logic device 104 is interfaced with at least one silicon bridge 110. In the example depicted in FIG. 5, each logic device 104 is interfaced with a plurality of silicon bridges 110. Similarly, each silicon bridge 110 may be interfaced with one compute die stack 130 of a common logic device 104. Each compute die stack 130 of a common logic device 104 is interfaced with at least one silicon bridge 110. In the example depicted in FIG. 5, each compute die stack 130 of a common logic device 104 is interfaced with a plurality of silicon bridges 110. Additionally, each silicon bridge 110 may be interfaced with the one or more compute dies 140 of a common logic device 104. The compute dies 140 of a common compute die stack 130 are interfaced with at least one silicon bridge 110. In the example depicted in FIG. 5, the compute dies 140 of a common compute die stack 130 is interfaced with a plurality of silicon bridges 110.

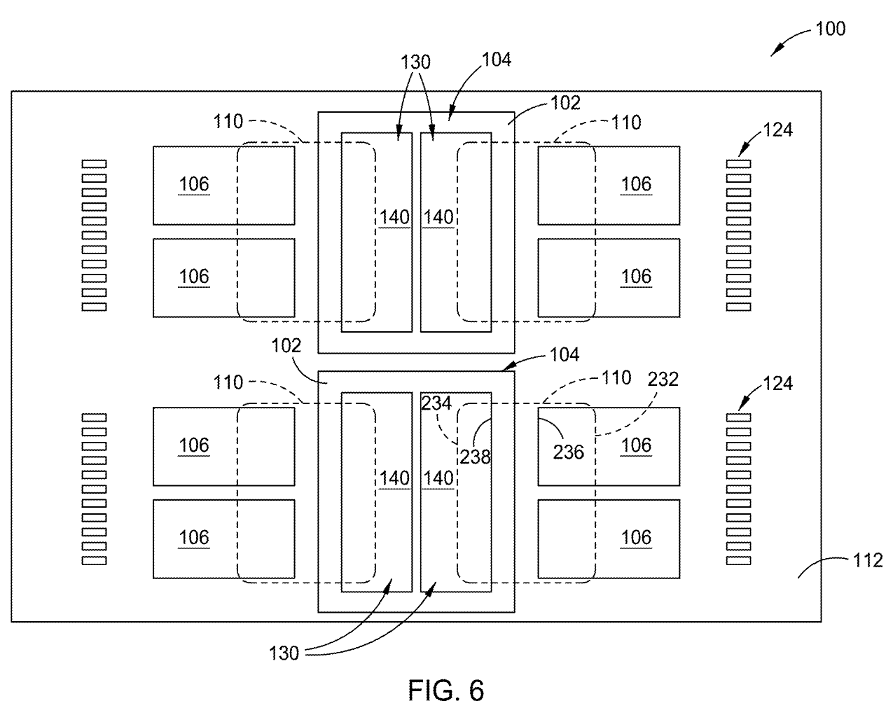

FIG. 6 depicts a variation to the chip package 100 having a first silicon bridge 110 interfaced with one or more memory stacks 106. The chip package 100 may include one or more other silicon bridges 110 interfaced with one or more other memory stacks 106. In the top view of the chip package 100 depicted in FIG. 6, each silicon bridge 110 (shown in phantom) is interfaced with one logic device 104 and two or more memory stacks 106. Each logic device 104 is interfaced with at least one silicon bridge 110. Each memory stack 106 is interfaced with at least one silicon bridge 110. In the example depicted in FIG. 6, each logic device 104 is interfaced with a plurality of silicon bridges 110. Similarly, each silicon bridge 110 may be interfaced with one compute die stack 130 of a common logic device 104 and two or more memory stacks 106. In other examples where the orientation of the compute die stacks 130 of a common logic device 104 are rotated 90 degrees, each silicon bridge 110 may be interfaced with one or more compute die stacks 130 of a common logic device 104 and two or more memory stacks 106.

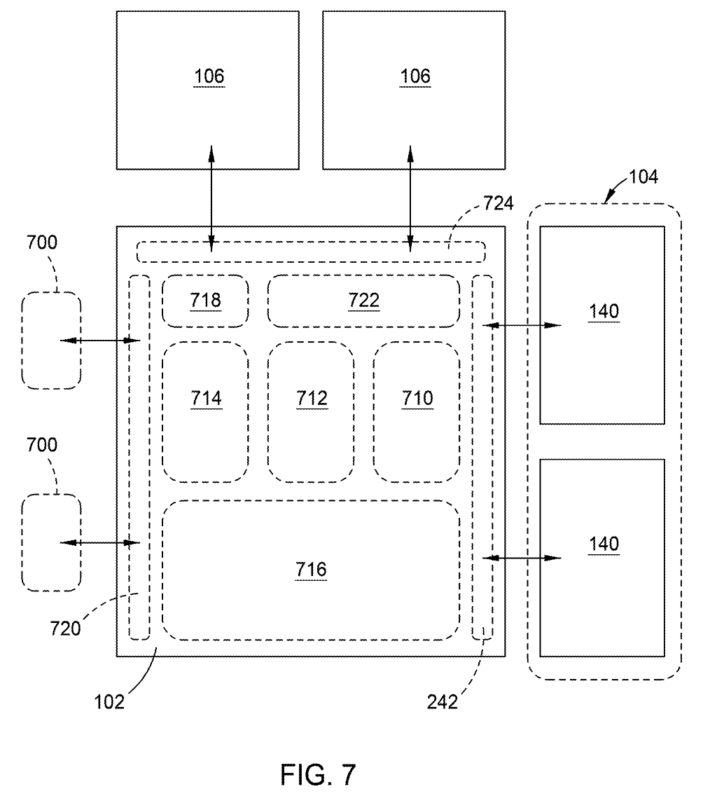

FIG. 7 is a schematic block diagram of one example of the IC interposer die 102 interfaced with one or more memory stacks 106 and one or more compute die stacks 130 that may be utilized in any of the chip packages contemplated herein, such as but not limited to chip packages 100, 300, 400, among others. The IC interposer die 102 may alternatively have other configurations. The functional circuitry of the IC interposer die 102 illustrated in FIG. 7 optionally includes logic circuitry 712 for processing signals passing through the interposer die 102. The functional circuitry of the IC interposer die 102 may also include cache memory circuity 710. The cache memory circuity 710 is coupled to both the compute dies 140 without routing signals through the package substrate 112 or the interposer layer 108. The cache memory circuity 710 provides a large common cache for the compute dies of the compute die stack 130 mounted to the IC interposer die 102.

The functional circuitry of the IC interposer die 102 may also include peripheral component interconnect express (PCIe) circuity 714, memory physical layer (PHY) circuitry 724 configured to communicate with the memory stack 106, die to die PHY 722 configured to communicate with at least one or more compute die stacks 130, and I/O PHY 720 configured to communicate with a remove device 700 outside of the chip package 100, or a printed circuit board 116 via the package substrate 112. One example of a remove device 700 may be the memory devices 128. The I/O PHY 720 may also be configured to communicate with other IC interposer dies 102 and/or compute die stacks 104 that are remove from the interposer die 102 in which the I/O PHY 720 resides. The I/O PHY 720 may also be configured to communicate with other memory stacks 106 residing in the chip package 100.

The functional circuitry of the IC interposer die 102 may also include functional block 716 that serializes and deserializes digital data used in high-speed chip-to-chip communication (e.g., serdes circuitry). The functional circuitry of the IC interposer die 102 may also include one or more other functional blocks 718 for performing other functions of a network on a chip (NOC).

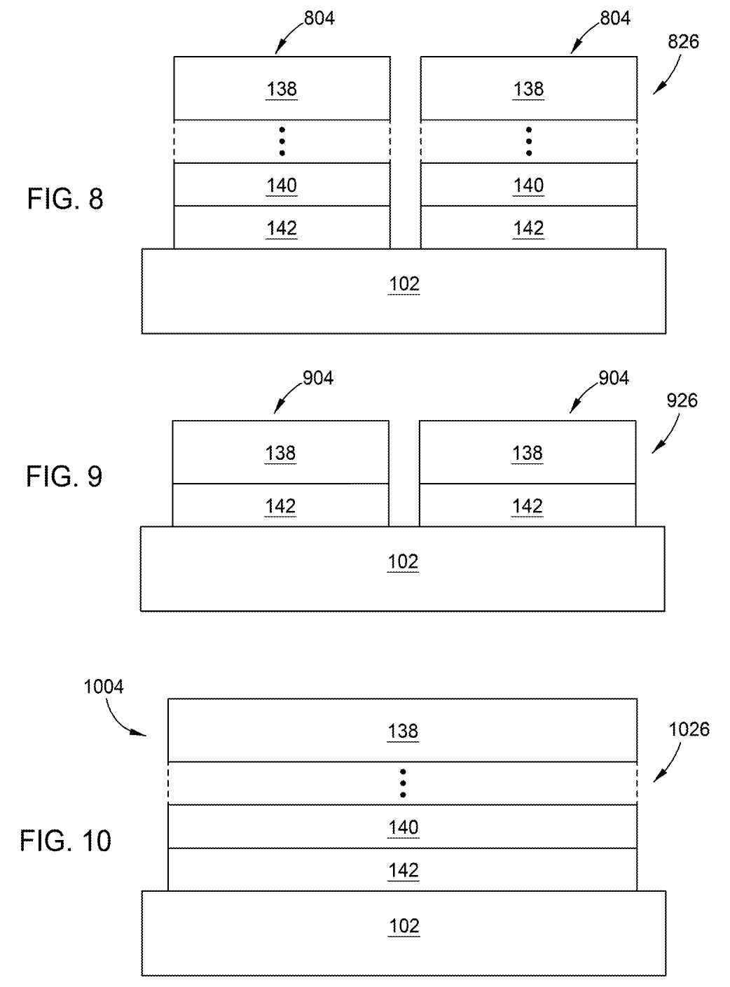

FIG. 8 is a schematic sectional view of one example of a logic device 826. The logic device 826 includes one or more compute die stacks 804 mounted on an IC interposer die 102. Two compute die stacks 804 are shown in FIG. 8, but the compute die stacks 804 may number from 1 to as many as can be reasonably accommodated on the IC interposer die 102. Each of the compute die stacks 804 may include one or more compute dies 140, and optional dummy dies as described above with reference to FIGS. 1 and 2. The logic device 826 may be utilized in any of the chip packages contemplated herein, such as but not limited to chip packages 100, 300, 400, among others.

In the example depicted in FIG. 8, two compute dies 140 are shown in each compute die stack 804. However, there may be none, one or more additional compute dies disposed between the compute die 140 and an optional carrier die 138.

FIG. 9 is a schematic sectional view of one example of a logic device 926. The logic device 926 includes one or more compute die stacks 904 mounted on the IC interposer die 102. Two compute die stacks 904 are shown in FIG. 9, but the compute die stacks 904 may number from 1 to as many as can be reasonably accommodated on the IC interposer die 102. Each of the compute die stacks 904 includes one or more compute dies 140, and may include optional dummy dies as described above with reference to FIGS. 1 and 2. The logic device 926 may be utilized in any of the chip packages contemplated herein, such as but not limited to chip packages 100, 300, 400, among others.

In the example depicted in FIG. 9, each compute die stack 904 includes a single compute die 140. Each compute die 140 is covered by a separate carrier die 138. Optionally, a single carrier die 138 may span to or more of the die stack 904.

FIG. 10 is a schematic sectional view of one example of a logic device 1026. The logic device 526 includes one or more compute die stacks 1004 mounted on an IC interposer die 102. A compute die stack 1004 is shown in FIG. 10, but the compute die stacks 1004 may number from 1 to as many as can be reasonably accommodated on the IC interposer die 102. The compute die stack 1004 includes one or more compute dies 140, and may include optional dummy dies as described above with reference to FIGS. 1 and 2. The logic device 1026 may be utilized in any of the chip packages contemplated herein, such as but not limited to chip packages 100, 300, 400, among others.

In the example depicted in FIG. 10, two compute dies 140 are shown in the compute die stack 1004. However, there may be none, one or more additional compute dies disposed between the compute die 140 and the optional carrier die 138.

The disclosed technology may also be described through the following non-limiting examples.

Example 1. A chip package including: a substrate; a logic device disposed over the substrate, the logic device including one or more compute dies; a memory stack disposed over the substrate adjacent the logic device; and a silicon bridge having a first portion and a second portion, the first portion disposed between the substrate and the logic device, the second portion disposed between the substrate and the memory stack.

Example 2. The chip package of example 1, wherein the one or more compute dies of the logic device further includes at least a first compute die and a second compute die.

Example 3. The chip package of example 2, wherein the first compute die and the second compute die includes central processing unit (CPU) cores.

Example 4. The chip package of example 2, wherein the first compute die includes accelerated compute cores and the second compute die includes central processing unit (CPU) cores.

Example 5. The chip package of example 2, wherein the first compute die and the second compute die includes accelerated compute cores.

Example 6. The chip package of example 2, wherein the logic device further includes a first integrated circuit (IC) interposer die having the first compute die and the second compute die mounted thereon.

Example 7. The chip package of example 1 further including a redistribution layer electrically coupling circuitry of the logic device with circuitry of the silicon bridge.

Example 8. The chip package of example 7 further including mold compound disposed between the redistribution layer and the substrate, the silicon bridge having portions of the mold compound disposed on opposite sides of the active silicon bridge.

Example 9. The chip package of example 7 further including an interposer disposed between the redistribution layer and the substrate, the interposer including a cavity in which the silicon bridge resides.

Example 10. The chip package of example 7, wherein the silicon bridge further includes an interposer disposed between the redistribution layer and the substrate.

Example 11. The chip package of example 1, wherein the silicon bridge further includes: a physical interface layer configured to communicate with the logic device; and memory controller circuitry coupled to the first and second physical interface layers.

Example 12. The chip package of example 11, wherein the memory controller circuitry further includes: off-package memory controller circuitry; and on-package memory controller circuitry.

Example 13. The chip package of example 12, wherein the on-package memory controller circuitry is disposed directly between the memory stack.

Example 14. The chip package of example 12, wherein the off-package memory controller circuitry is configured to communicate with double data rate synchronous dynamic random-access memory (DDR SDRAM).

Example 15. The chip package of example 1 further including: an electrically floating metal layer disposed on a side of the silicon bridge opposite the logic device.

Example 16. The chip package of example 15 further including a plurality of thermal vias providing conductive thermal paths between the metal layer and the silicon bridge.

Example 17. The chip package of example 16, wherein the metal layer extend laterally beyond the silicon bridge.

Example 18. The chip package of example 15, wherein the metal layer further includes apertures aligned with power pads formed on the silicon bridge.

Example 19. The chip package of example 2, wherein the logic device further includes: an IC interposer die coupled to both the first and second compute dies without routing signals through the package substrate; and cache memory circuity disposed in the IC interposer die and coupled to both the first and second compute dies without routing signals through the package substrate.

Example 20. The chip package of example 2, wherein the logic device further includes: an IC interposer die coupled to both the first and second compute dies without routing signals through the package substrate; a network on a chip (NOC) circuitry disposed in the IC interposer die; peripheral component interconnect express (PCIe) circuity disposed in the IC interposer die; memory physical layer (PHY) circuitry configured to communicate with the memory stack disposed directly above the silicon bridge; die to die PHY configured to communicate with at least one of the first and second compute dies; and I/O PHY configured to communicate with a device remote from the chip package.

Example 21. A chip package including: a substrate; a logic device disposed over the substrate, the logic device including one or more compute dies; a memory stack disposed over the substrate adjacent the logic device; a silicon bridge having a physical interface layer and memory controller circuitry, the physical interface layer disposed below the logic device, the memory controller circuitry having on-package memory controller circuitry disposed below the memory stack; and a redistribution layer electrically coupling circuitry of the logic device with circuitry of the silicon bridge.

Example 22. The chip package of example 21 further including mold compound disposed between the redistribution layer and the substrate, the silicon bridge having portions of the mold compound disposed on opposite sides of the silicon bridge.

Example 23. The chip package of example 21 further including an interposer disposed between the redistribution layer and the substrate, the interposer including a cavity in which the silicon bridge resides.

Example 24. The chip package of example 21, wherein the silicon bridge further includes an interposer disposed between the redistribution layer and the substrate.

Example 25. The chip package of example 21, wherein the memory controller circuitry further includes off-package memory controller circuitry.

Example 26. The chip package of example 25, wherein the off-package memory controller circuitry is configured to communicate with double data rate synchronous dynamic random-access memory (DDR SDRAM).

Example 27. The chip package of example 21 further including an electrically floating metal layer disposed on a side of the silicon bridge opposite the logic device.

Example 28. The chip package of example 27 further including a plurality of thermal vias providing conductive thermal paths between the metal layer and the silicon bridge.

Example 29. The chip package of example 28, wherein the metal layer extend laterally beyond the silicon bridge.

Example 30. The chip package of example 27, wherein the metal layer further includes apertures aligned with power pads formed on the silicon bridge.

Example 31. The chip package of example 21, wherein the one or more compute dies of the logic device further includes at least a first compute die and a second compute die.

Example 32. The chip package of example 31, wherein the first compute die and the second compute die includes central processing unit (CPU) cores.

Example 33. The chip package of example 31, wherein the first compute die includes accelerated compute cores and the second compute die includes central processing unit (CPU) cores.

Example 34. The chip package of example 31, wherein the first compute die and the second compute die includes accelerated compute cores.

Example 35. The chip package of example 31, wherein the logic device further includes a first integrated circuit (IC) interposer die having the first compute die and the second compute die mounted thereon.

Example 36. The chip package of example 31, wherein the logic device further includes: an IC interposer die coupled to both the first and second compute dies without routing signals through the package substrate; and cache memory circuity disposed in the IC interposer die and coupled to both the first and second compute dies without routing signals through the package substrate.

Example 37. The chip package of example 31, wherein the logic device further includes: an IC interposer die coupled to both the first and second compute dies without routing signals through the package substrate; a network on a chip (NOC) circuitry disposed in the IC interposer die; peripheral component interconnect express (PCIe) circuity disposed in the IC interposer die; memory physical layer (PHY) circuitry configured to communicate with the memory stack disposed directly above the silicon bridge; die to die PHY configured to communicate with at least one of the first and second compute dies; and I/O PHY configured to communicate with a device remote from the chip package.

Example 38. An electronic device including: a printed circuit board (PCB); and the chip package of example 1 mounted to the PCB.

Example 39. The electronic device of example 38, wherein the silicon bridge further includes: a physical interface layer configured to communicate with the logic device; and memory controller circuitry coupled to the first and second physical interface layers.

Example 40. The electronic device of example 39, wherein the memory controller circuitry further includes: off-package memory controller circuitry; and on-package memory controller circuitry.

Example 41. The electronic device of example 40 further including off-package memory coupled to the PCB, the off-package memory communicatively coupled to the off-package memory controller circuitry.

Example 42. The electronic device of example 41, wherein the off-package memory is volatile memory.

Example 43. The electronic device of example 41, wherein the off-package memory is double data rate synchronous dynamic random-access memory (DDR SDRAM).

Example 44. The electronic device of example 41, wherein the on-package memory controller circuitry is disposed directly between the memory stack.

Example 45. The electronic device of example 38 further including a redistribution layer electrically coupling circuitry of the logic device with circuitry of the silicon bridge.

Example 46. The electronic device of example 45 further including mold compound disposed between the redistribution layer and the substrate, the silicon bridge having portions of the mold compound disposed on opposite sides of the silicon bridge.

Example 47. The electronic device of example 45 further including: an interposer disposed between the redistribution layer and the substrate, the interposer including a cavity in which the silicon bridge resides.

Example 48. The electronic device of example 45, wherein the silicon bridge further includes an interposer disposed between the redistribution layer and the substrate.

Example 49. The electronic device of example 38 further including: an electrically floating metal layer disposed on a side of the silicon bridge opposite the logic device.

Example 50. The electronic device of example 49 further including: a plurality of thermal vias providing conductive thermal paths between the metal layer and the silicon bridge.

Example 51. The electronic device of example 50, wherein the metal layer extend laterally beyond the silicon bridge.

Example 52. The electronic device of example 50, wherein the metal layer further includes apertures aligned with power pads formed on the silicon bridge.

Example 53. The electronic device of example 38, wherein the one or more compute dies of the logic device further includes first and second compute dies.

Example 54. The electronic device of example 53 wherein the chip package further includes: an IC interposer die coupled to both the first and second compute dies without routing signals through the package substrate; and cache memory circuity disposed in the IC interposer die and coupled to both the first and second compute dies without routing signals through the package substrate.

Example 55. The electronic device of example 53, wherein the logic device further includes: an IC interposer die coupled to both the first and second compute dies without routing signals through the package substrate; a network on a chip (NOC) circuitry disposed in the IC interposer die; peripheral component interconnect express (PCIe) circuity disposed in the IC interposer die; memory physical layer (PHY) circuitry configured to communicate with the memory stack disposed directly above the silicon bridge; die to die PHY configured to communicate with at least one of the first and second compute dies; and I/O PHY configured to communicate with a device remote from the chip package.

Example 56. The electronic device of example 53, wherein the first compute die and the second compute die includes central processing unit (CPU) cores.

Example 57. The electronic device of example 53, wherein the first compute die includes accelerated compute cores and the second compute die includes central processing unit (CPU) cores.

Example 58. The electronic device of example 53, wherein the first compute die and the second compute die includes accelerated compute cores.

Example 59. The electronic device of example 53, wherein the logic device further includes a first integrated circuit (IC) interposer die having the first compute die and the second compute die mounted thereon.

Example 60. A chip package including: a substrate; a plurality of silicon bridges disposed in a common layer and electrically and mechanically coupled to the substrate, at least a first silicon bridge of the plurality of silicon bridges includes a plurality of decoupling capacitors; a redistribution layer disposed on the plurality of silicon bridges; a logic device disposed over the redistribution layer, the logic device including one or more compute dies; and a memory stack disposed over the redistribution layer adjacent the logic device.

Example 61. The chip package of Example 60, wherein the plurality of decoupling capacitors of the first silicon bridge includes deep trench capacitors.

Example 62. The chip package of Example 60, wherein the plurality of decoupling capacitors of the first silicon bridge includes metal insulator metal (MIM) capacitors.

Example 63. The chip package of Example 60, wherein the plurality of decoupling capacitors of the first silicon bridge includes metal-oxide-semiconductor (MOS) capacitors.

Example 64. The chip package of Example 60, wherein the first silicon bridge includes through silicon vias.

Example 65. The chip package of Example 64, wherein the through silicon vias disposed through the first silicon bridge are configured to connect power to the logic device.

Example 66. The chip package of Example 64, wherein the through silicon vias disposed through the first silicon bridge are configured to connect data signals to the logic device.

Example 67. The chip package of Example 60, wherein the logic device is coupled to the memory stack through at least one of the plurality of silicon bridges.

Example 68. The chip package of Example 60, wherein the plurality of silicon bridges are disposed in mold compound.

Example 69. The chip package of Example 68 further including a conductive post extending through the mold compound.

Example 70. The chip package of Example 60, wherein conductive post is electrically floating.

Example 71. The chip package of Example 60, wherein the plurality of silicon bridges further includes a second silicon bridge containing one or more active devices.

Example 72. A chip package including: a substrate; a layer of mold compound; a redistribution layer disposed on layer of mold compound; a logic device disposed over the redistribution layer, the logic device including one or more compute dies; a memory stack disposed over the redistribution layer adjacent the logic device; and a plurality of silicon bridges disposed in the layer of mold compound, at least a first silicon bridge of the plurality of silicon bridges including a plurality of decoupling capacitors coupled with the logic device.

Example 73. The chip package of Example 72 further including: a build up layer disposed between the first silicon bridge and the redistribution layer, the build up layer having routing coupling the plurality of decoupling capacitors with the logic device.

Example 74. The chip package of Example 73, wherein the build up layer and the first silicon bridge are disposed in a cavity formed in the layer of mold compound.

Example 75. The chip package of Example 73 further including: solder interconnects coupling the redistribution layer and the logic device.

Example 76. The chip package of Example 73 further including: solder interconnects coupling the redistribution layer and the logic device.

Example 77. The chip package of Example 72, wherein the plurality of silicon bridges further includes a second silicon bridge containing one or more active devices.

Example 78. A chip package including: a substrate; a layer of mold compound; a redistribution layer disposed on layer of mold compound; a logic device disposed over the redistribution layer, the logic device including one or more compute dies; a memory stack disposed over the redistribution layer adjacent the logic device; a plurality of silicon bridges disposed in the layer of mold compound, at least a first silicon bridge of the plurality of silicon bridges including a plurality of deep trench capacitors coupled with the logic device, wherein the first silicon bridge includes through silicon vias; and a conductive post extending through the mold compound.

Example 79. The chip package of Example 78, wherein the plurality of silicon bridges further includes a second silicon bridge containing one or more active devices.

Thus, the chip packages disclosed above arrange memory stacks as a unified memory device efficiently available through a silicon bridge that contains active and/or passive circuitry. The silicon bridge couples one or more compute dies to one or more memory stacks. The short routing provided by the silicon bridge improves speed and performance, while reducing the space needed for complex routing as required in conventional packages. The modular arrangement enabled by the silicon bridge architecture makes the chip package readily scalable and adapted to be configured for various compute applications without the need for new die or interposer designs. As a result, the chip package provides increased application flexibility at reduced manufacturing costs.

While the foregoing is directed to embodiments of the present invention, other and further embodiments of the invention may be devised without departing from the basic scope thereof, and the scope thereof is determined by the claims that follow.

What is claimed is:

1. A chip package comprising:
a substrate;
a plurality of silicon bridges disposed in a common a layer and electrically and mechanically coupled to the substrate, at least a first silicon bridge of the plurality of silicon bridges includes a plurality of decoupling capacitors;
a redistribution layer disposed on the plurality of silicon bridges;
a logic device disposed over the redistribution layer, the logic device comprising one or more compute dies; and
a memory stack disposed over the redistribution layer adjacent the logic device.

2. The chip package of claim 1, wherein the plurality of decoupling capacitors of the first silicon bridge comprises deep trench capacitors.

3. The chip package of claim 1, wherein the plurality of decoupling capacitors of the first silicon bridge comprises metal insulator metal (MIM) capacitors.

4. The chip package of claim 1, wherein the plurality of decoupling capacitors of the first silicon bridge comprises metal-oxide-semiconductor (MOS) capacitors.

5. The chip package of claim 1, wherein the first silicon bridge comprises through silicon vias.

6. The chip package of claim 5, wherein the through silicon vias disposed through the first silicon bridge are configured to connect power to the logic device.

7. The chip package of claim 5, wherein the through silicon vias disposed through the first silicon bridge are configured to connect data signals to the logic device.

8. The chip package of claim 1, wherein the logic device is coupled to the memory stack through at least one of the plurality of silicon bridges.

9. The chip package of claim 1, wherein the plurality of silicon bridges are disposed in mold compound.

10. The chip package of claim 9 further comprising a conductive post extending through the mold compound.

11. The chip package of claim 1, wherein conductive post is electrically floating.

12. The chip package of claim 1, wherein the plurality of silicon bridges further comprises a second silicon bridge containing one or more active devices.

13. A chip package comprising:
a substrate;
a layer of mold compound;
a redistribution layer disposed on the layer of mold compound;
a logic device disposed over the redistribution layer, the logic device comprising one or more compute dies;
a memory stack disposed over the redistribution layer adjacent the logic device; and
a plurality of silicon bridges disposed in the layer of mold compound, at least a first silicon bridge of the plurality of silicon bridges including a plurality of decoupling capacitors coupled with the logic device.

14. The chip package of claim 13 further comprising:
a build up layer disposed between the first silicon bridge and the redistribution layer, the build up layer having routing coupling the plurality of decoupling capacitors with the logic device.

15. The chip package of claim 14, wherein the build up layer and the first silicon bridge are disposed in a cavity formed in the layer of mold compound.

16. The chip package of claim 14 further comprising:
solder interconnects coupling the redistribution layer and the logic device.

17. The chip package of claim 14 further comprising:
solder interconnects coupling the redistribution layer and the logic device.

18. The chip package of claim 13, wherein the plurality of silicon bridges further comprises a second silicon bridge containing one or more active devices.

19. A chip package comprising:
a substrate;
a layer of mold compound;
a redistribution layer disposed on a layer of mold compound;
a logic device disposed over the redistribution layer, the logic device comprising one or more compute dies;
a memory stack disposed over the redistribution layer adjacent the logic device;
a plurality of silicon bridges disposed in the layer of mold compound, at least a first silicon bridge of the plurality of silicon bridges including a plurality of deep trench capacitors coupled with the logic device, wherein the first silicon bridge comprises through silicon vias; and
a conductive post extending through the mold compound.

20. The chip package of claim 19, wherein the plurality of silicon bridges further comprises a second silicon bridge containing one or more active devices.
